(19) United States
(12) Patent Application Publication
(10) Pub. No.: US 2023/0197584 A1
(43) Pub. Date: Jun. 22, 2023

(54) MOUNTING STRUCTURE FOR SEMICONDUCTOR MODULE

(71) Applicant: ROHM CO., LTD., Kyoto-shi, Kyoto (JP)

(72) Inventor: Ippei YASUTAKE, Kyoto-shi, Kyoto (JP)

(21) Appl. No.: 17/926,414

(22) PCT Filed: May 17, 2021
(86) PCT No.: PCT/JP2021/018637

§ 371 Date: Nov. 18, 2022

(30) Foreign Application Priority Data
May 26, 2020 (JP) 2020-091223

(51) Int. Cl. H01L 23/495; H01L 23/40; H01L 23/473

(52) U.S. Cl. CPC H01L 23/49568; H01L 23/40; H01L 23/473

(57) ABSTRACT

A mounting structure for a semiconductor module, includes: a substrate having an obverse surface and a reverse surface facing away from each other in a thickness direction; a semiconductor module mounted on a side of the substrate toward which the obverse surface is directed; and a heat dissipating member that dissipates heat from the semiconductor module. The substrate has a cavity penetrating in the thickness direction. The heat dissipating member includes a body portion located on a side of the substrate toward which the reverse surface is directed, and a protruding portion received in the cavity. The semiconductor module is bonded to the protruding portion.

### TECHNICAL FIELD

The present disclosure relates to a mounting structure for a semiconductor module.

### BACKGROUND ART

Conventionally, mounting structures for a semiconductor module have been used in automobiles and industrial equipment. Patent Document 1 discloses a mounting structure for a semiconductor module. The mounting structure disclosed in the document includes a semiconductor module built with a semiconductor element, such as a MOSFET. The semiconductor module is mounted on a substrate. In the mounting structure, the semiconductor module is bonded to a heat dissipating member.

### PRIOR ART DOCUMENT

### Patent Document

Patent Document 1: JP-A-2013-94022

### SUMMARY OF THE INVENTION

### Problem to be Solved by the Invention

The heat dissipating member above is provided in an upright position with respect to the substrate. The mounting structure of such a configuration tends to be relatively large in the thickness direction of the substrate.

In view of the circumstances described above, an aim of the present disclosure is to provide a lower-profile mounting structure for a semiconductor module.

### Means to Solve the Problem

The present disclosure provides a mounting structure for a semiconductor module, including: a substrate including an obverse surface and a reverse surface facing away from each other in a thickness direction; a semiconductor module mounted on a side of the substrate toward which the obverse surface is directed; and a heat dissipating member that dissipates heat from the semiconductor module. The substrate has a cavity penetrating in the thickness direction. The heat dissipating member includes a body portion located on a side of the substrate toward which the reverse surface is directed, and a protruding portion received in the cavity. The semiconductor module is bonded to the protruding portion.

Preferably, the heat dissipating member includes a cooling passage through which a coolant flows.

Preferably, the cooling passage overlaps with the protruding portion as viewed in the thickness direction.

Preferably, the semiconductor module includes a semiconductor element, an island portion to which the semiconductor element is bonded, a lead terminal electrically connected to the semiconductor element, and a resin member covering the semiconductor element.

Preferably, the island portion includes an exposed surface that is exposed from the resin member, and the exposed surface is bonded to the protruding portion.

Preferably, the lead terminal includes a base portion protruding from the resin member in a direction intersecting the thickness direction, and an end portion extending along the thickness direction. The end portion penetrates the substrate.

Preferably, the end portion protrudes from the reverse surface of the substrate and is spaced apart from the heat dissipating member.

Preferably, the mounting structure further includes an insulating layer disposed between the reverse surface of the substrate and the body portion of the heat dissipating member.

Preferably, the insulating layer contains a gel material.

Preferably, the insulating layer contains a ceramic material.

Preferably, the cavity comprises a through hole having a closed edge as viewed in the thickness direction.

Preferably, the cavity comprises a cutout portion having an open edge as viewed in the thickness direction.

Preferably, the mounting structure further includes a fastening member that fastens the substrate and the heat dissipating member with a space therebetween.

Preferably, the protruding portion includes a bonding surface that is bonded to the semiconductor module.

Preferably, the bonding surface is flush with the obverse surface

Preferably, the bonding surface is offset from the obverse surface in the thickness direction toward which the obverse surface is directed.

Preferably, the bonding surface is located within the cavity in the thickness direction.

### Advantages of Invention

The present disclosure enables the thickness reduction of a mounting structure for a semiconductor module.

Other features and advantages of the present disclosure will be more apparent from the detailed description given below with reference to the accompanying drawings.

### BRIEF DESCRIPTION OF THE DRAWINGS

FIG. 1 is a fragmentary perspective view of a mounting structure for a semiconductor module, according to a first embodiment of the present disclosure.

FIG. 2 is a fragmentary plan view of the mounting structure according to the first embodiment of the present disclosure.

FIG. 3 is a sectional view taken along line III-III of FIG. 2.

FIG. 4 is a fragmentary sectional view taken along line III-III of FIG. 2.

FIG. 5 is a fragmentary sectional view taken along line V-V of FIG. 2.

FIG. 6 is an enlarged fragmentary sectional view of the mounting structure according to the first embodiment of the present disclosure.

FIG. 7 is an enlarged fragmentary sectional view of a first variation of the bonding layer of the mounting structure according to the first embodiment of the present disclosure.

FIG. 8 is an enlarged fragmentary sectional view of the mounting structure according to the first embodiment of the present disclosure.

FIG. 9 is an enlarged fragmentary sectional view of a first variation of the insulating layer of the mounting structure according to the first embodiment of the present disclosure.

FIG. 10 is an enlarged fragmentary sectional view of a second variation of the insulating layer of the mounting structure according to the first embodiment of the present disclosure.

FIG. 11 is a fragmentary plan view of a mounting structure for a semiconductor module, according to a first variation of the first embodiment of the present disclosure.

FIG. 12 is a fragmentary plan view of a mounting structure for a semiconductor module, according to a second embodiment of the present disclosure.

FIG. 13 is a sectional view taken along line XIII-XIII of FIG. 12.

FIG. 14 is a fragmentary plan view of a mounting structure for a semiconductor module, according to a third embodiment of the present disclosure.

FIG. 15 is a fragmentary sectional view of a mounting structure for a semiconductor module, according to a fourth embodiment of the present disclosure.

FIG. 16 is a fragmentary sectional view of a mounting structure for a semiconductor module, according to a fifth embodiment of the present disclosure.

### MODE FOR CARRYING OUT THE INVENTION

Preferred embodiments of the present disclosure are described below with reference to the drawings.

### First Embodiment

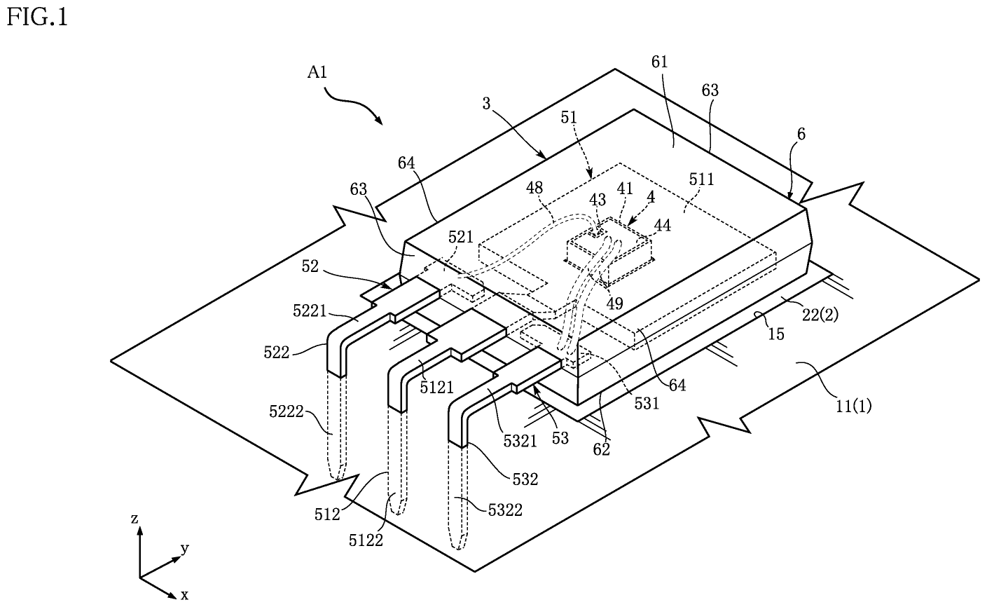

FIGS. 1 to 10 show a mounting structure for a semiconductor module, according to a first embodiment of the present disclosure. The mounting structure A1 for a semiconductor module of this embodiment includes a substrate 1, a heat dissipating member 2, a semiconductor module 3, a bonding layer 7, an insulating layer 8 and a fastening member 9. The mounting structure A1 can be used in power supply unit of an automobile, for example.

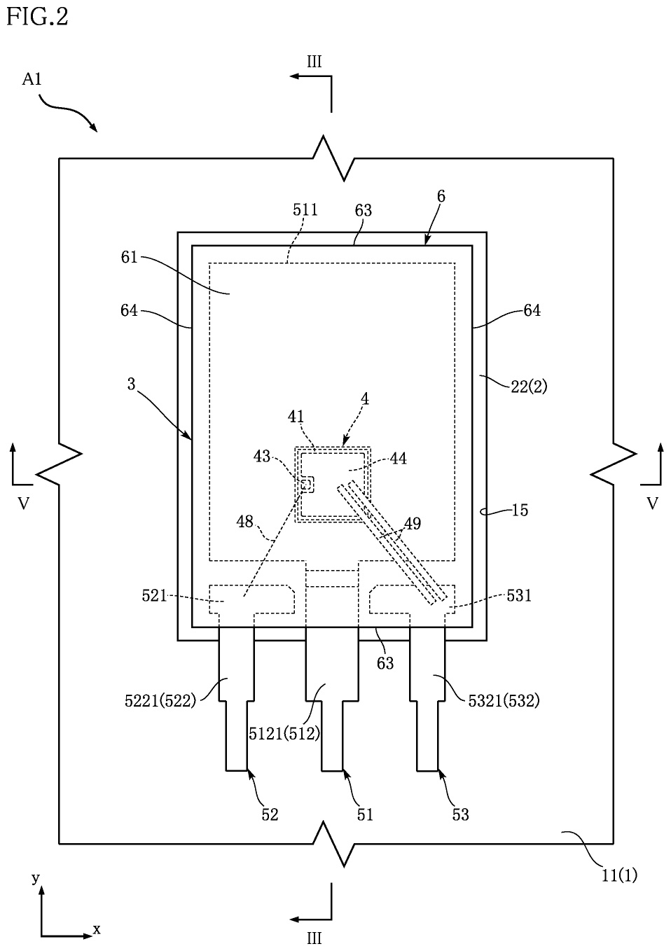

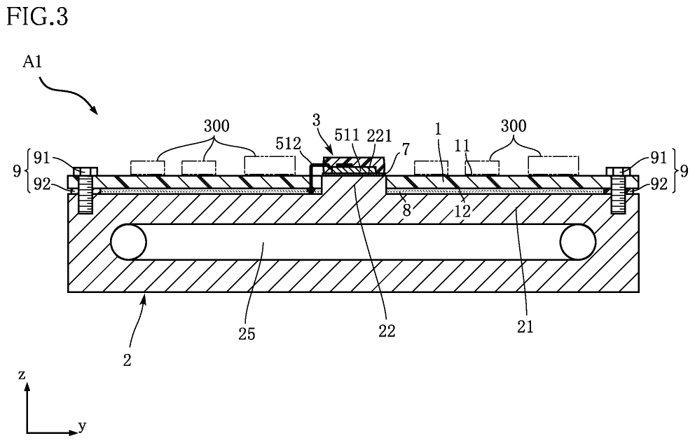

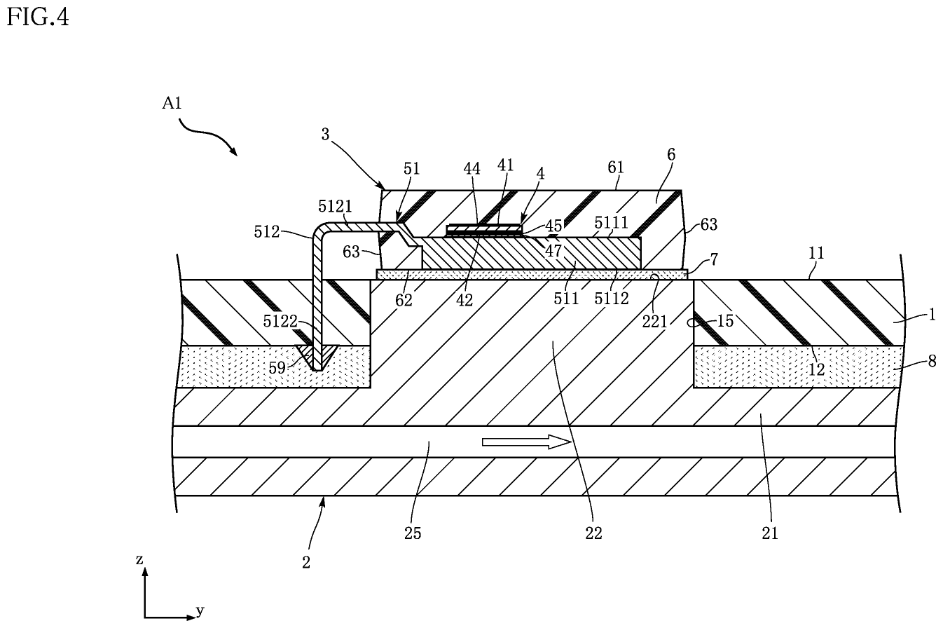

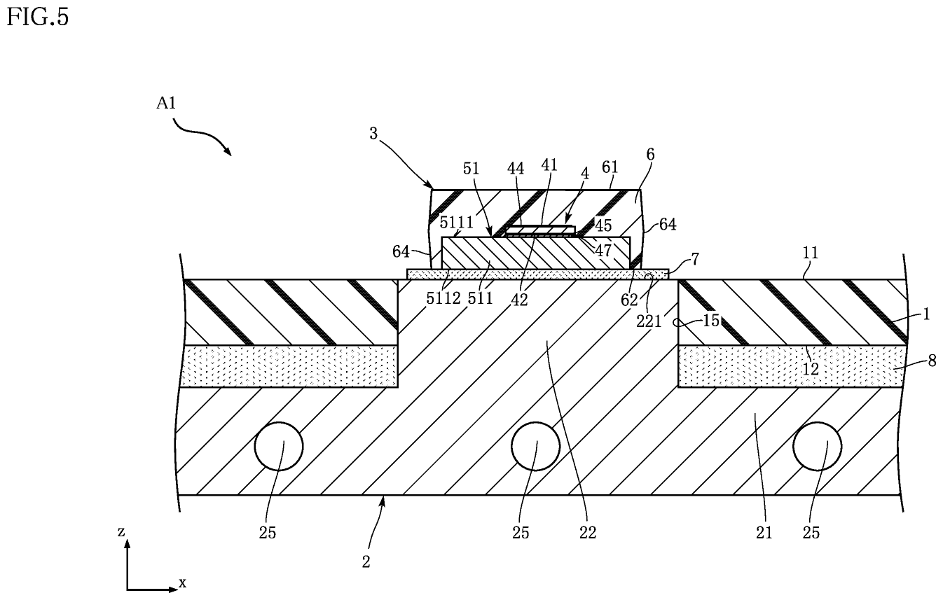

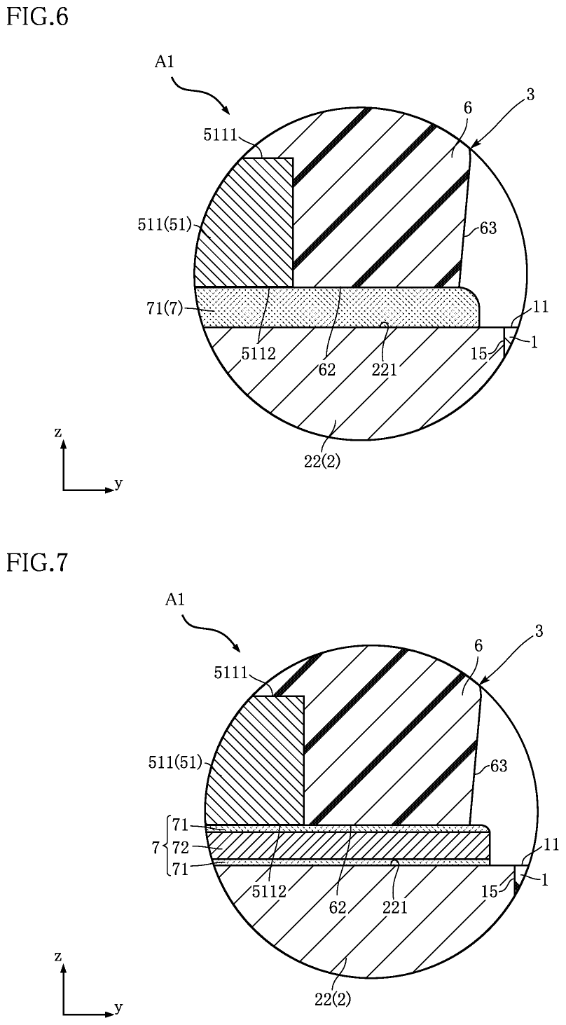

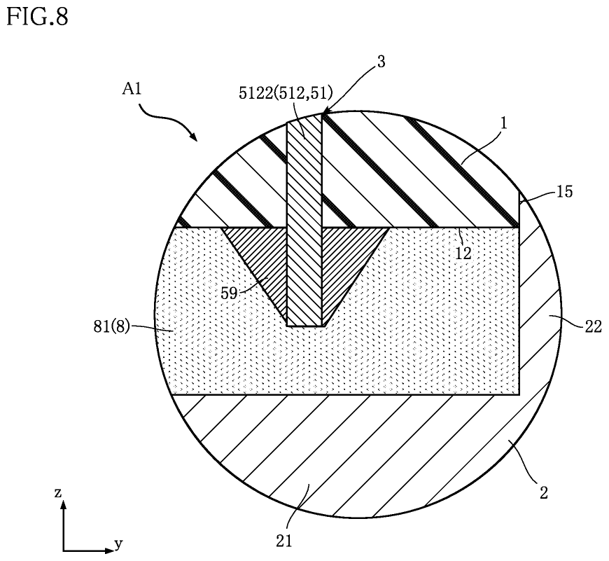

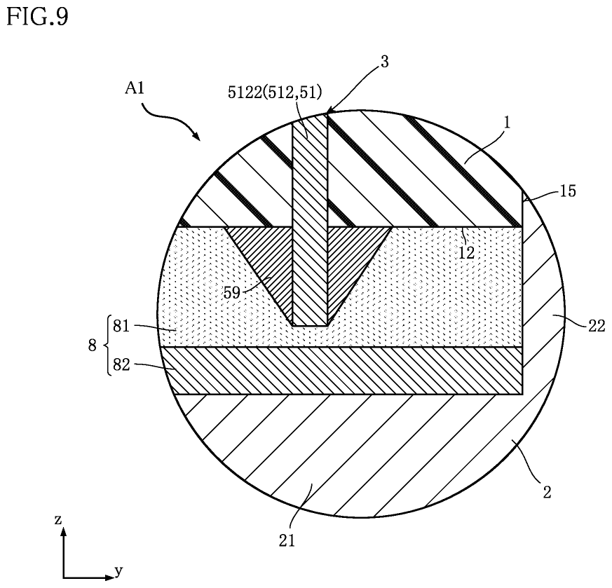

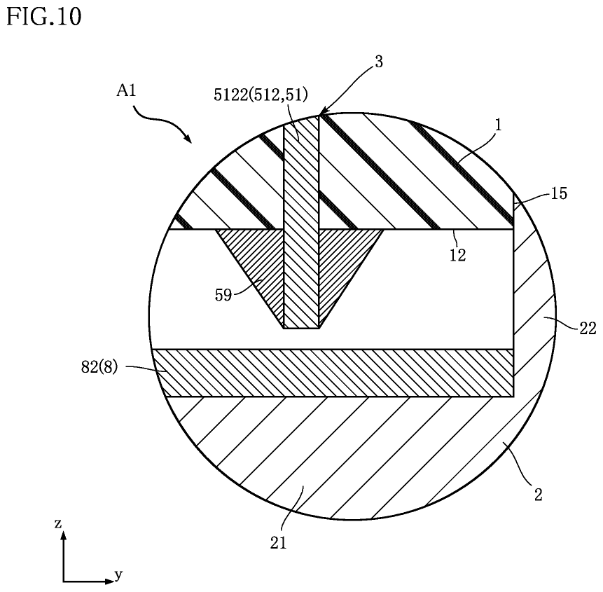

FIG. 1 is a fragmentary perspective view of the mounting structure A1. FIG. 2 is a fragmentary plan view of the mounting structure A1. FIG. 3 is a sectional view taken along line III-III of FIG. 2. FIG. 4 is a fragmentary sectional view taken along line III-III of FIG. 2. FIG. 5 is a fragmentary sectional view taken along line V-V of FIG. 2. FIG. 6 is an enlarged fragmentary sectional view of the mounting structure A1. FIG. 7 is an enlarged fragmentary sectional view of a first variation of the bonding layer of the mounting structure A1. FIG. 8 is an enlarged fragmentary sectional view of the mounting structure A1. FIG. 9 is an enlarged fragmentary sectional view of a first variation of the insulating layer of the mounting structure A1. FIG. 10 is an enlarged fragmentary sectional view of a second variation of the insulating layer of the mounting structure A1. In these figures, the z direction corresponds to the thickness direction of the present disclosure. The x and y directions are perpendicular to each other and also to the z direction.

The substrate 1 has an obverse surface 11 and a reverse surface 12 facing away from each other in the z direction. The substrate 1 includes a main body made of grass epoxy resin, and a wiring pattern (not shown) formed on the main body. The substrate 1 may be provided with connectors and terminals (not shown) as necessary for external connections.

In the example shown in FIG. 3, the semiconductor module 3 and a plurality of electronic components 300 are mounted on or close to the obverse surface 11 of the substrate 1. Additionally, other electronic components may be mounted on or close to the reverse surface 12 of the substrate 1.

The substrate 1 includes a cavity 15. As shown in FIGS. 4 and 5, the cavity 15 penetrates the substrate 1 in the z direction. The shape and location of the cavity 15 is not particularly limited. As shown in FIG. 2, the cavity 15 of this embodiment is a through hole having a closed edge as viewed in the z direction. The shape of the cavity 15 as viewed in the z direction may be rectangular, polygonal, circular, elliptical and so on. In the illustrated example, the cavity 15 is rectangular as viewed in the z direction.

The heat dissipating member 2 dissipates heat from the semiconductor module 3. The material of the heat dissipating member 2 is not particularly limited, and may be a metal such as aluminum or stainless steel. As shown in FIGS. 3 to 5, the heat dissipating member 2 of this embodiment includes a body portion 21 and a protruding portion 22. The body portion 21 is located on or over the reverse surface 12 of the substrate 1. In the illustrated example, the body portion 21 is a plate-like portion extending in the x and y directions.

The protruding portion 22 protrudes from the body portion 21 in the z direction. At least a part of the protruding portion 22 is received in the cavity 15 of the substrate 1. The shape and location of the protruding portion 22 is not particularly limited. As shown in FIG. 2, the protruding portion 22 of the illustrated example is rectangular as viewed in the z direction and is press-fitted into the cavity 15. The protruding portion 22 has a bonding surface 221. The bonding surface 221 is a flat plane perpendicular to the z-direction. The bonding surface 221 of this embodiment is flush with (or substantially flush with) the obverse surface 11 of the substrate 1.

The heat dissipating member 2 has a cooling passage 25. The cooling passage 25 is a channel for passing a coolant for dissipating heat from the semiconductor module 3. The coolant is not particularly limited and may be a liquid, such as water or oil, or a gas, such as air or nitrogen. In the illustrated example, a part of the cooling passage 25 overlaps with the protruding portion 22 as viewed in the z direction.

The fastening member 9 fastens the substrate 1 and the body portion 21 of the heat dissipating member 2 relative to each other with a space in between. The configuration of the fastening member 9 is not particularly limited. As shown in FIG. 3, the fastening member 9 of this embodiment is composed of a screw 91 and a spacer 92. The spacer 92 is disposed between the reverse surface 12 of the substrate 1 and the body portion 21 of the heat dissipating member 2 and may be an annular member made of resin, for example. The screw 91 is inserted through the substrate 1 and the spacer 92 and engaged with a threaded hole provided in the body portion 21 of the heat dissipating member 2, thereby joining the substrate 1 and the heat dissipating member 2 together.

The semiconductor module 3 is of a type to be mounted on a substrate 1. The semiconductor module 3 includes a semiconductor element 4, leads 51, 52 and 53, wires 48 and 49, and a resin member 6.

The semiconductor element 4 is a main electronic component of the semiconductor module 3. The semiconductor element 4 of this embodiment is a power semiconductor element, such as a power metal oxide semiconductor field effect transistor (MOSFET) or an insulated gate bipolar transistor (IGBT). The semiconductor element 4 is not limited to this, and alternative examples include other transistors, various diodes, and various thyristors, as well as IC chips, such as control ICs. The semiconductor element 4 is rectangular in this embodiment but the present disclosure is not limited to this. The semiconductor element 4 includes an element obverse surface 41, an element reverse surface 42, a reverse-surface electrode 45, and obverse-surface electrodes 43 and 44.

The semiconductor element 4 is made of a semiconductor material, such as Si, SiC or GaN. The element obverse surface 41 faces in the z1 direction. The element reverse surface 42 faces in the z2 direction. In the present embodiment, each of the element obverse surface 41 and the element reverse surface 42 is flat.

Each of the reverse-surface electrode 45 and the obverse-surface electrodes 43 and 44 is a plating layer of metal, such as Cu, Ni, Al or Au. For the semiconductor element 4 that is a power MOSFET, the reverse-surface electrode 45 may be a drain electrode, the obverse-surface electrode 43 may be a gate electrode, and the obverse-surface electrode 44 may be a source electrode. For the semiconductor element 4 that is an IGBT, the reverse-surface electrode 45 may be a collector electrode, the obverse-surface electrode 43 may be a gate electrode, and the obverse-surface electrode 44 may be an emitter electrode.

In this embodiment, the reverse-surface electrode 45 is formed on the element reverse surface 42. The reverse-surface electrode 45 is rectangular as viewed in the z direction. All the edges of the reverse-surface electrode 45 overlap with the edges of the element reverse surface 42 as viewed in the z direction. The reverse-surface electrode 45 covers the entire surface of the element reverse surface 42.

In this embodiment, the obverse-surface electrodes 43 and 44 are formed on the element obverse surface 41. The obverse-surface electrode 43 has a smaller area than the obverse-surface electrode 44. The wire 48 is connected to the obverse-surface electrode 43, and the wires 49 are connected to the obverse-surface electrode 44.

The leads 51, 52 and 53 are made of an electrically conductive material. The electrically conductive material may be Cu, for example. The leads 51, 52 and 53 are bonded to the substrate 1 and form conduction paths between the semiconductor element 4 and the substrate 1. The number of leads included in the semiconductor module is not limited to three. For example, two leads may be included, or four or more leads may be included. The number of leads can be adjusted depending on the type of the semiconductor element 4, for example.

The lead 51 includes an island portion 511 and a lead terminal 512.

The island portion 511 is for mounting the semiconductor element 4 thereon. The island portion 511 includes a mount surface 5111 and an exposed surface 5112.

The mount surface 5111 faces in one sense of the z direction. The entire mount surface 5111 is flat. Unlike the illustrated example, the island portion 511 may include one or more recesses, grooves, and/or through holes in the mount surface 5111 as necessary. The mount surface 5111 may be coated with a plating layer (not shown in the figures) made of Ag, for example. In this embodiment, the reverse-surface electrode 45 of the semiconductor element 4 is electrically bonded to the mount surface 5111 by, for example, a conductive bonding material 47. The conductive bonding material 47 may be solder, Ag paste, sintered Ag or sintered Cu, for example.

The exposed surface 5112 faces in the other sense of the z direction. The entire exposed surface 5112 is flat. The entire exposed surface 5112 is exposed from the resin member 6.

The lead terminal 512 is electrically connected to the reverse-surface electrode 45 of the semiconductor element 4 via the island portion 511 and the wires 49. The lead terminal 512 includes a base portion 5121 and an end portion 5122. The base portion 5121 protrudes from a resin end surface 63 of the resin member 6 in the y direction, which is a direction perpendicular to the z direction. The end portion 5122 is connected to the end of the base portion 5121 and extends in the z direction. The end portion 5122 penetrates the substrate 1 and protrudes from the reverse surface 12. The protruded part of the end portion 5122 is electrically bonded to the substrate 1 by solder 59, for example.

As shown in FIG. 1, the lead 52 includes a pad portion 521 and a lead terminal 522.

The pad portion 521 is longer than the lead terminal 522 in the x direction. The entire pad portion 521 is covered with the resin member 6. As shown in FIGS. 1 and 2, the wire 48 is connected to the pad portion 521.

As shown in FIG. 1, the lead terminal 522 includes a base portion 5221 and an end portion 5222. The base portion 5221 protrudes from the resin end surface 63 of the resin member 6 in the direction perpendicular to the z direction (in the y direction). The end portion 5222 is connected to the end of the base portion 5221 and extends in the z direction. The end portion 5222 penetrates the substrate 1 and protrudes from the reverse surface 12. The protruded part of the end portion 5222 is electrically bonded to the substrate 1 by solder 59, for example.

The lead 53 includes a pad portion 531 and a lead terminal 532.

As shown in FIGS. 1 and 2, the pad portion 531 is longer than the lead terminal 532 in the x direction. The entire pad portion 531 is covered with the resin member 6. As shown in FIGS. 1 and 2, the wires 49 are connected to the pad portion 531.

As shown in FIG. 1, the lead terminal 532 includes a base portion 5321 and an end portion 5322. The base portion 5321 protrudes from the resin end surface 63 of the resin member 6 in the direction perpendicular to the z direction (in the y direction). The end portion 5322 is connected to the end of the base portion 5321 and extends in the z direction. The end portion 5322 penetrates the substrate 1 and protrudes from the reverse surface 12. The protruded part of the end portion 5322 is electrically bonded to the substrate 1 by solder 59, for example.

The leads 51, 52 and 53 are spaced apart from each other. The lead terminal 512 of the lead 51 is located between the lead terminal 522 of the lead 52 and the lead terminal 532 of the lead 53 in the x direction. The parts of the lead terminals 512, 522 and 532 that are exposed from the resin member 6 may be coated with a plating layer (not shown) of a metal, such as Ag.

As shown in FIGS. 1 and 2, the wire 48 is bonded to the pad portion 521 at one end, and to the semiconductor element 4 (the obverse-surface electrode 43) at the other end. The wire 48 electrically connects the pad portion 521 and the obverse-surface electrode 43. The wire 48 of this embodiment is mainly made of gold (Au). The main material is not limited to this and may be aluminum (Al) or copper (Cu), for example. In addition, as a substitute for the wire 48 that is in the form of a strip, a ribbon wire having a wide flat shape or a clip made of metal, such as Cu, may be used.

As shown in FIGS. 2 and 3, each of the wires 49 is bonded to the pad portion 531 at one end, and to the semiconductor element 4 (the obverse-surface electrode 44) at the other end. The Each wires 49 electrically connect the pad portion 531 and the obverse-surface electrode 44. The wires 49 of this embodiment are mainly made of aluminum (Al). The main material is not limited to this and may be gold (Au) or copper (Cu), for example. Although the semiconductor module 3 of this embodiment includes two wires 49, the number of the wires 49 is not limited to two. For example, a single wire 49 may be included. The wires 49 have a larger diameter than the wire 48. In addition, as a substitute for each wire 49 that is in the form of a strip, a ribbon wire having a wide flat shape or a clip made of metal, such as Cu, may be used.

The material, number, diameter and so on of the wires 48 and 49 can be designed as necessary for the current passed through these wires.

The resin member 6 covers the semiconductor element 4, portions of the leads 51, 52 and 53, and the wires 48 and 49. The resin member 6 is made of an electrically insulating, thermosetting synthetic resin. The resin member 6 of this embodiment is made of a black epoxy resin. The resin member 6 includes a resin obverse surface 61, a resin reverse surface 62, a pair of resin end surfaces 63 and a pair of resin side surfaces 64.

As shown in FIGS. 1, 4 and 5, the resin obverse surface 61 faces in one sense of the z direction. As shown in FIGS. 1, 4 and 5, the resin reverse surface 62 faces in the other sense of the z direction.

As shown in FIGS. 2 and 4, the pair of resin end surfaces 63 are spaced apart from each other in the y direction. The pair of resin end surfaces 63 face away from each other in the y direction. As shown in FIG. 4, the opposite ends of each resin end surface 63 in the z direction are connected to the resin obverse surface 61 and the resin reverse surface 62. In this embodiment, each of the lead 51 (the lead terminal 512), the lead 52 (the lead terminal 522) and the lead 53 (the lead terminal 532) has a part exposed from one of the resin end surfaces 63.

As shown in FIG. 5, the pair of resin side surfaces 64 are spaced apart from each other in the x direction. The pair of resin side surfaces 64 face away from each other in the x direction. The opposite ends of each resin side surface 64 in the z direction is connected to the resin obverse surface 61 and the resin reverse surface 62.

As shown in FIGS. 4 and 5, the bonding layer 7 bonds the semiconductor module 3 and the heat dissipating member 2. Specifically, the bonding layer 7 of this embodiment bonds the exposed surface 5112 of the island portion 511 of the lead 51 to the bonding surface 221 of the protruding portion 22.

The configuration of the bonding layer 7 is not particularly limited. The bonding layer 7 may be either electrically conductive or insulative. In this embodiment, the bonding layer 7 is made of an insulating material because it is preferable to insulate the lead 51, which is electrically connected to the reverse-surface electrode 45 of the semiconductor element 4, from the heat dissipating member 2.

FIG. 6 shows an example of the bonding layer 7. The bonding layer 7 of the illustrated example is composed of a gel layer 71, such as a layer of an insulating gel material or grease.

FIG. 7 shows a first variation of the bonding layer 7. The bonding layer 7 of this variation includes gel layers 71 and a sheet layer 72. The sheet layer 72 is made of an insulating material, such as a ceramic material. In the illustrated example, each gel layer 71 is provided on the opposite surfaces of the sheet layer 72.

The insulating layer 8 is disposed between the substrate 1 and the body portion 21 of the heat dissipating member 2. The insulating layer 8 insulates the heat dissipating member 2 from the wiring pattern (not shown) of the substrate 1, the lead 51 (the lead terminal 512), the lead 52 (the lead terminal 522) and the lead 53 (the lead terminal 532).

FIG. 8 shows an example of the insulating layer 8. The insulating layer 8 of the illustrated example is composed of a gel layer 81, such as a layer of an insulating gel material or grease.

FIG. 9 shows a first variation of the insulating layer 8. The insulating layer 8 of this variation includes a gel layer 81 and a sheet layer 82. The sheet layer 82 is made of an insulating material, such as a ceramic material. In the illustrated example, the gel layer 81 is disposed between the sheet layer 82 and the body portion 21.

FIG. 10 shows a second variation of the insulating layer 8. The insulating layer 8 of this variation includes a sheet layer 82 but without a gel layer 81. The sheet layer 82 may be disposed along the body portion 21 and spaced apart from the lead 51 (the lead terminal 512), the lead 52 (the lead terminal 522) and the lead 53 (the lead terminal 532).

The following describes advantages of the mounting structure A1 for a semiconductor module.

According to the present embodiment, the semiconductor module 3 is bonded to the protruding portion 22 of the heat dissipating member 2 received in the cavity 15 of the substrate 1. That is, the heat dissipating member 2 can be positioned to lie generally along the x and y directions, rather than in the state of standing up in the z direction from the substrate 1, for example. This allows the mounting structure A1 to be thinner in the z direction.

The heat dissipating member 2 is provided with the cooling passage 25. A coolant, such as water, passing through the cooling passage 25 can improve dissipation of heat from the semiconductor module 3. The cooling passage 25 overlaps with the protruding portion 22 as viewed in the z direction. This configuration is preferable for effectively dissipating heat transferred from the semiconductor module 3 to the protruding portion 22.

The semiconductor element 4 of the semiconductor module 3 is mounted on the island portion 511 of the lead 51. The exposed surface 5112 of the island portion 511 is exposed from the resin member 6 and bonded to the bonding surface 221 of the protruding portion 22 of the heat dissipating member 2 via the bonding layer 7. This further improves dissipation of heat from the semiconductor module 3 to the protruding portion 22.

The bonding layer 7 may include the gel layer 71, in which case the gel layer 71 can fill small asperities possibly present on the exposed surface 5112 and/or the bonding surface 221. This is preferable for improving dissipation of heat from the semiconductor module 3. In addition, the bonding layer 7 may include the sheet layer 72, which is preferable for improving the mechanical and dielectric strengths of the bonding layer 7.

The lead terminal 512 includes the base portion 5121 and the end portion 5122. The end portion 5122 is inserted through the substrate 1. This allows the semiconductor module 3 to be mounted on the substrate 1 with the island portion 511 and the resin member 6 positioned along the substrate 1 (along the x and y directions). This arrangement is preferable for the mounting structure A1 to be thinner. For similar advantages, the lead terminal 522 includes the base portion 5221 and the end portion 5222, and the lead terminal 532 includes the base portion 5321 and the end portion 5322.

The insulating layer 8 is disposed between the reverse surface 12 of the substrate 1 and the body portion 21 of the heat dissipating member 2. This prevents undesirable conduction between the substrate 1 and the heat dissipating member 2. In addition, providing the insulating layer 8 between the reverse surface 12 of the substrate 1 and the body portion 21 of the heat dissipating member 2 makes it possible to reduce the distance between them, as compared with the case where the reverse surface 12 and the body portion 21 are separated only by a gap (air). This arrangement is preferable for the mounting structure A1 to be thinner.

The insulating layer 8 may include the gel layer 81, in which case the gel layer 81 can fill surface asperities possibly present on the substrate 1 and/or the body portion 21. This is preferable for more reliably insulating the substrate 1 and the heat dissipating member 2. In addition, the insulating layer 8 may include the sheet layer 82, which is preferable for improving the mechanical and dielectric strengths of the insulating layer 8.

The cavity 15 has an edge defining a closed shape as viewed in the z direction. That is, the cavity 15 can be formed at a location spaced apart from the edge of the substrate 1. Thus, the location of the semiconductor module 3 on the substrate 1 (the mounting structure A1) can be selected more flexibly.

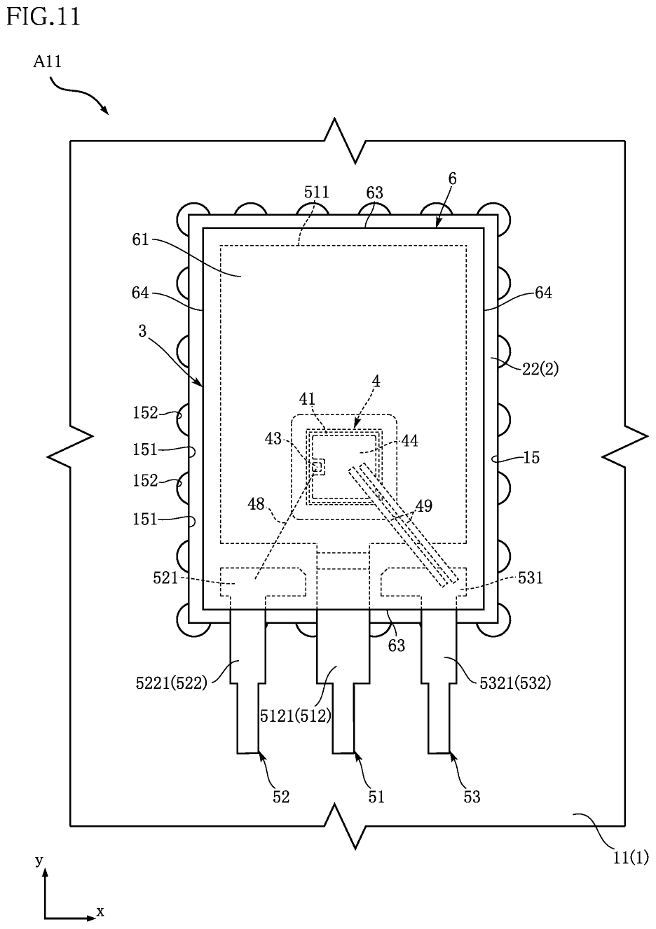

FIGS. 11 to 16 show other variations and embodiments of the present disclosure. In these figures, the elements that are identical or similar to those of the foregoing embodiment are denoted by the same reference signs as those used for the foregoing embodiment.

### First Variation of First Embodiment

FIG. 11 shows a first variation of the mounting structure A1 for a semiconductor module. The mounting structure A1l for a semiconductor module of this variation differs from the foregoing embodiment in the shape of the cavity 15.

The cavity 15 of this variation includes a plurality of contact portions 151 and a plurality of recessed portions 152. The contact portions 151 are in contact with the protruding portion 22 of the heat dissipating member 2. The recessed portions 152 and the contact portion 151 are alternately arranged. The recessed portions 152 are recessed in the direction away from the protruding portion 22 as viewed in the z direction. The cavity 15 of this configuration can be formed by making a plurality of through holes in an insulating plate, which is to be processed into the substrate 1, and removing portions of insulating plate along the through holes.

As can be seen from this variation, the specific configuration of the cavity 15 is not particularly limited. The configuration of this variation can be appropriately employed in other embodiments.

### Second Embodiment

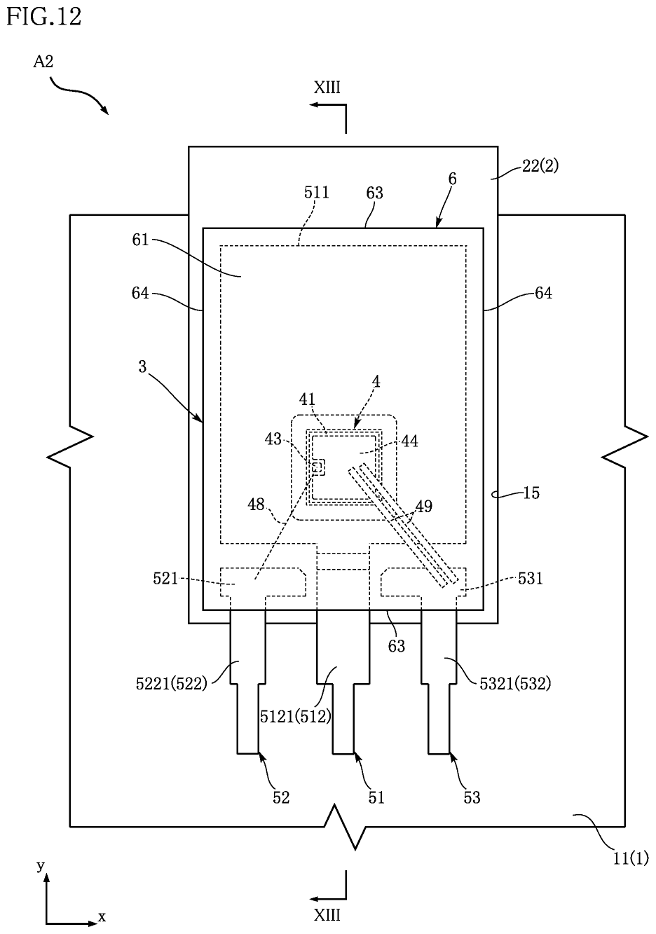

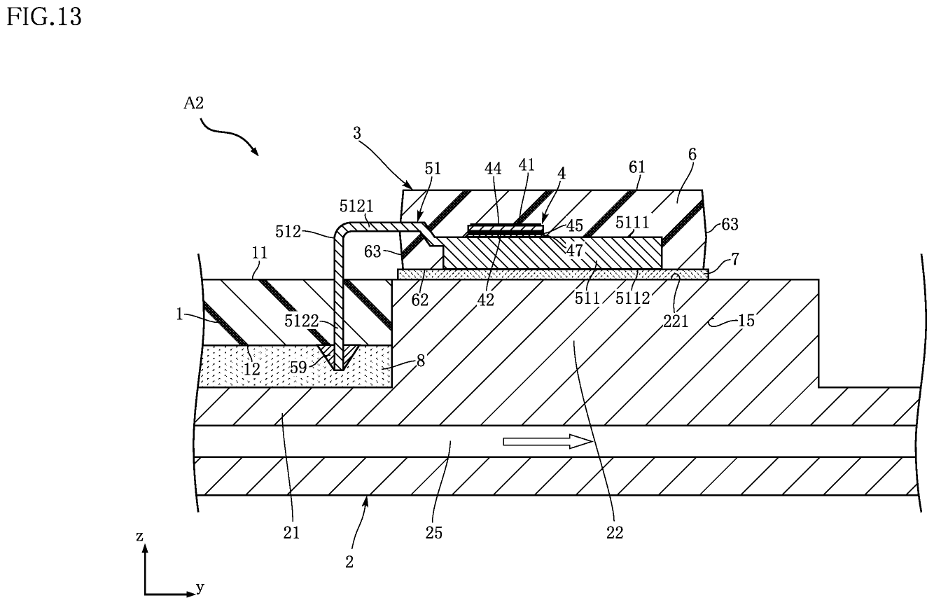

FIGS. 12 and 13 show a mounting structure for a semiconductor module, according to a second embodiment of the present disclosure. The mounting structure A2 for a semiconductor module of this embodiment differs from the first embodiment described above in the configuration of the cavity 15 and the protruding portion 22.

The cavity 15 of this embodiment is a cutout portion having an open edge as viewed in the z direction. More specifically, the cavity 15 has a shape that is recessed inward in the y direction from an edge of the substrate 1 as viewed in the z direction.

At least a part of the protruding portion 22 is received in the cavity 15. In the illustrated example, a part of the protruding portion 22 protrudes out of the cavity 15 in the y direction. Unlike the illustrated example, the entire protruding portion 22 may be contained within the cavity 15 as viewed in the z direction.

The configuration of this embodiment is also preferable for the mounting structure A2 to be thinner. As can be seen from this embodiment, the specific configuration of the cavity 15 and the protruding portion 22 is not particularly limited.

### Third Embodiment

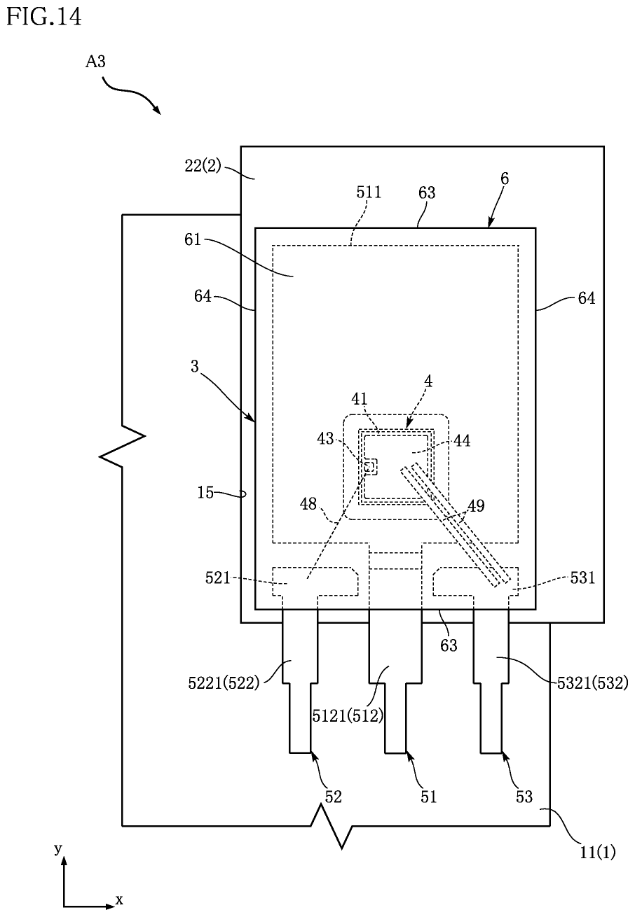

FIG. 14 shows a mounting structure for a semiconductor module, according to a third embodiment of the present disclosure. The mounting structure A3 for a semiconductor module of this embodiment differs from the foregoing embodiments in the configuration of the cavity 15 and the protruding portion 22.

The cavity 15 of this embodiment is a cutout portion having an open edge as viewed in the z direction. More specifically, the cavity 15 has a shape that is recessed inward in the x and y directions from two edges of the substrate 1 as viewed in the z direction.

At least a part of the protruding portion 22 is received in the cavity 15. In the illustrated example, a part of the protruding portion 22 protrudes out of the cavity 15 in the x direction and also in the y direction. Unlike the illustrated example, the entire protruding portion 22 may be contained within the cavity 15 as viewed in the z direction. In another example, the entire length of the protruding portion 22 either in the x direction or in the y direction may be contained within the cavity 15 as viewed in the z direction.

The configuration of this embodiment is also preferable for the mounting structure A3 to be thinner. As can be seen from this embodiment, the specific configuration of the cavity 15 and the protruding portion 22 is not particularly limited.

### Fourth Embodiment

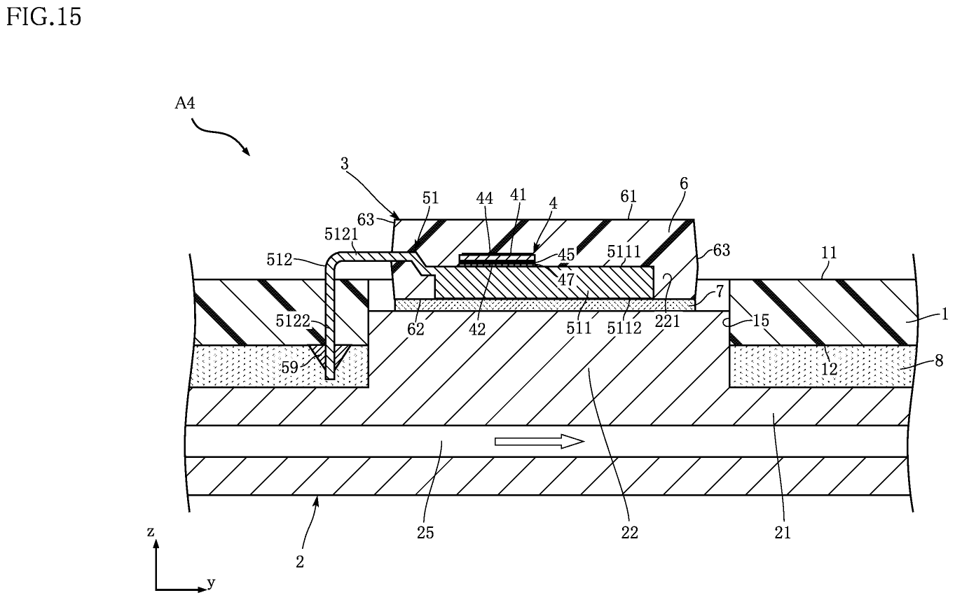

FIG. 15 shows a mounting structure for a semiconductor module, according to a fourth embodiment of the present disclosure. The mounting structure A4 for a semiconductor module of this embodiment differs from the foregoing embodiments mainly in the configuration of the protruding portion 22 of the heat dissipating member 2.

In this embodiment, the bonding surface 221 of the protruding portion 22 is located within the cavity 15 in the z direction. That is, the bonding surface 221 is offset from the obverse surface 11 of the substrate 1 toward the reverse surface 12.

In this embodiment, the resin member 6 is smaller than the cavity 15 and the bonding surface 221 as viewed in the z direction. A part of the semiconductor module 3, including the exposed surface 5112, is located within the cavity 15 in the z direction.

The configuration of this embodiment is also preferable for the mounting structure A4 to be thinner. In addition, this configuration makes it possible to further reduce the distance between the semiconductor module 3 and the cooling passage 25 and thus preferable for improving dissipation of heat from the semiconductor module 3. In addition, since a portion of the semiconductor module 3 is contained in the cavity 15, the mounting structure A4 can thinner.

### Fifth Embodiment

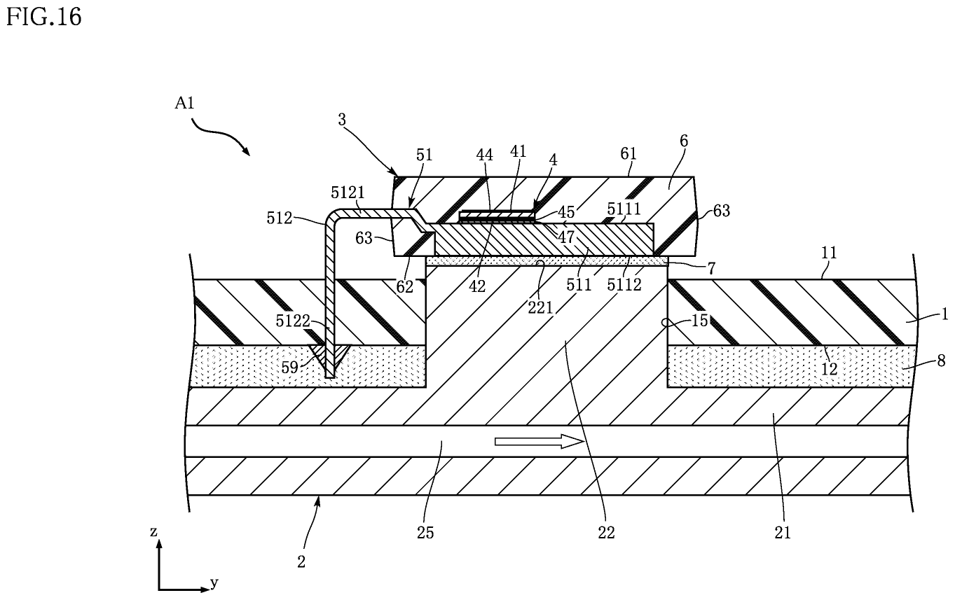

FIG. 16 shows a mounting structure for a semiconductor module, according to a fifth embodiment of the present disclosure. The mounting structure A5 for a semiconductor module of this embodiment differs from the foregoing embodiments mainly in the configuration of the protruding portion 22 of the heat dissipating member 2.

In this embodiment, the bonding surface 221 is offset from the obverse surface 11 in the z direction toward which the obverse surface 11 is directed. In the illustrated example, the cavity 15 and the protruding portion 22 are smaller than the resin member 6 as viewed in the z direction.

The configuration of this embodiment is also preferable for the mounting structure A5 to be thinner. In addition, reducing the size of the cavity 15 and the protruding portion 22 as viewed in the z direction contributes enables the size reduction of the mounting structure A5 as viewed in the z direction.

The mounting structure for a semiconductor module according to the present disclosure is not limited to the foregoing embodiments and variations. The specific configuration of each part of the mounting structure according to the present disclosure may be varied in design in many ways.

Clause 1.

A mounting structure for a semiconductor module, comprising:

a substrate including an obverse surface and a reverse surface facing away from each other in a thickness direction;

a semiconductor module mounted on a side of the substrate toward which the obverse surface is directed; and

a heat dissipating member that dissipates heat from the semiconductor module,

wherein the substrate has a cavity penetrating in the thickness direction,

the heat dissipating member includes a body portion located on a side of the substrate toward which the reverse surface is directed, and a protruding portion received in the cavity, and

the semiconductor module is bonded to the protruding portion.

Clause 2.

The mounting structure according to Clause 1, wherein the heat dissipating member includes a cooling passage through which a coolant flows.

Clause 3.

The mounting structure according to Clause 2, wherein the cooling passage overlaps with the protruding portion as viewed in the thickness direction.

Clause 4.

The mounting structure according to any one of Clauses 1 to 3, wherein the semiconductor module includes a semiconductor element, an island portion to which the semiconductor element is bonded, a lead terminal electrically connected to the semiconductor element, and a resin member covering the semiconductor element.

Clause 5.

The mounting structure according to Clause 4, wherein the island portion includes an exposed surface that is exposed from the resin member, and the exposed surface is bonded to the protruding portion.

Clause 6.

The mounting structure according to Clause 5, wherein the lead terminal includes a base portion protruding from the resin member in a direction intersecting the thickness direction, and an end portion extending along the thickness direction, and

the end portion penetrates the substrate.

Clause 7.

The mounting structure according to Clause 6, wherein the end portion protrudes from the reverse surface of the substrate and is spaced apart from the heat dissipating member.

Clause 8.

The mounting structure according to any one of Clauses 1 to 7, further comprising an insulating layer disposed between the reverse surface of the substrate and the body portion of the heat dissipating member.

Clause 9.

The mounting structure according to Clause 8, wherein the insulating layer contains a gel material.

Clause 10.

The mounting structure according to Clause 8 or 9, wherein the insulating layer contains a ceramic material.

Clause 11.

The mounting structure according to any one of Clauses 1 to 10, wherein the cavity comprises a through hole having a closed edge as viewed in the thickness direction.

Clause 12.

The mounting structure according to any one of Clauses 1 to 10, wherein the cavity comprises a cutout portion having an open edge as viewed in the thickness direction.

Clause 13.

The mounting structure according to any one of Clauses 1 to 12, further comprising a fastening member that fastens the substrate and the heat dissipating member with a space therebetween.

Clause 14.

The mounting structure according to any one of Clauses 1 to 13, wherein the protruding portion includes a bonding surface that is bonded to the semiconductor module.

Clause 15.

The mounting structure according to Clause 14, wherein the bonding surface is flush with the obverse surface.

Clause 16.

The mounting structure according to Clause 14, wherein the bonding surface is offset from the obverse surface in the thickness direction toward which the obverse surface is directed.

Clause 17.

The mounting structure according to Clause 14, wherein the bonding surface is located within the cavity in the thickness direction.

### REFERENCE NUMERALS

A1, A11, A2, A3, A4, A5: Mounting structure
1: Substrate 2: Heat dissipating member
3: Semiconductor module
4: Semiconductor element 6: Resin member 7: Bonding layer
8: Insulating layer 9: Fastening member 11: Obverse surface
12: Reverse surface 15: Cavity 21: Body portion
22: Protruding portion 25: Cooling passage
41: Element obverse surface 42: Element reverse surface
43, 44: Obverse-surface electrode 45: Reverse-surface electrode
47: Conductive bonding material 48, 49: Wire
51, 52, 53: Lead 59: Solder 61: Resin obverse surface
62: Resin reverse surface 63: Resin end surface
64: Resin side surface 71: Gel layer 72: Sheet layer
81: Gel layer 82: Sheet layer 91: Screw 92: Spacer
151: Contact portion 152: Recessed portion
221: Bonding surface
300: Electronic component 511: Island portion
512: Lead terminal 521: Pad portion
522: Lead terminal 531: Pad portion
532: Lead terminal 5111: Mount surface
5112: Exposed surface 5121: Base portion 5122: End portion
5221: Base portion 5222: End portion
5321: Base portion 5322: End portion

1. A mounting structure for a semiconductor module, comprising:
a substrate including an obverse surface and a reverse surface facing away from each other in a thickness direction;
a semiconductor module mounted on a side of the substrate toward which the obverse surface is directed; and
a heat dissipating member that dissipates heat from the semiconductor module,
wherein the substrate has a cavity penetrating in the thickness direction,
the heat dissipating member includes a body portion located on a side of the substrate toward which the reverse surface is directed, and a protruding portion received in the cavity, and
the semiconductor module is bonded to the protruding portion.

2. The mounting structure according to claim 1, wherein the heat dissipating member includes a cooling passage through which a coolant flows.

3. The mounting structure according to claim 2, wherein the cooling passage overlaps with the protruding portion as viewed in the thickness direction.

4. The mounting structure according to claim 1, wherein the semiconductor module includes a semiconductor element, an island portion to which the semiconductor element is bonded, a lead terminal electrically connected to the semiconductor element, and a resin member covering the semiconductor element.

5. The mounting structure according to claim 4, wherein the island portion includes an exposed surface that is exposed from the resin member, and the exposed surface is bonded to the protruding portion.

6. The mounting structure according to claim 5, wherein the lead terminal includes a base portion protruding from the resin member in a direction intersecting the thickness direction, and an end portion extending along the thickness direction, and
the end portion penetrates the substrate.

7. The mounting structure according to claim 6, wherein the end portion protrudes from the reverse surface of the substrate and is spaced apart from the heat dissipating member.

8. The mounting structure according to claim 1, further comprising an insulating layer disposed between the reverse surface of the substrate and the body portion of the heat dissipating member.

9. The mounting structure according to claim 8, wherein the insulating layer contains a gel material.

10. The mounting structure according to claim 8, wherein the insulating layer contains a ceramic material.

11. The mounting structure according to claim 1, wherein the cavity comprises a through hole having a closed edge as viewed in the thickness direction.

12. The mounting structure according to claim 1, wherein the cavity comprises a cutout portion having an open edge as viewed in the thickness direction.

13. The mounting structure according to claim 1, further comprising a fastening member that fastens the substrate and the heat dissipating member with a space therebetween.

14. The mounting structure according to claim 1, wherein the protruding portion includes a bonding surface that is bonded to the semiconductor module.

15. The mounting structure according to claim 14, wherein the bonding surface is flush with the obverse surface.

16. The mounting structure according to claim 14, wherein the bonding surface is offset from the obverse surface in the thickness direction toward which the obverse surface is directed.

17. The mounting structure according to claim 14, wherein the bonding surface is located within the cavity in the thickness direction.
